(19) United States
(12) Patent Application Publication
(10) Pub. No.: US 2023/0053215 A1
(43) Pub. Date: Feb. 16, 2023

(54) HIERARCHICAL REDUCED-ORDER MATRIX GENERATION DEVICE

(71) Applicant: Hitachi, Ltd., Tokyo (JP)

(72) Inventors: Akiyasu MIYAMOTO, Tokyo (JP); Taizou MIYAZAKI, Tokyo (JP)

(21) Appl. No.: 17/915,663

(22) PCT Filed: Mar. 31, 2021
(86) PCT No.: PCT/JP2021/014029

§ 371 Date: Sep. 29, 2022

(30) Foreign Application Priority Data
Apr. 10, 2020 (JP) 2020-071055

(51) Int. Cl. G06F 17/16; G06F 30/10

(52) U.S. Cl. CPC G06F 17/16; G06F 30/10

(57) ABSTRACT

During model-based development, a processing target is sometimes broken down into partial structures. At such time, a long calculation time and a large quantity of computer resources are required if each partial structure has a large number of degrees of freedom. The present invention is a hierarchical reduced-order matrix generation device 600 that generates a hierarchical reduced-order matrix for performing numerical analysis of a physical object, and has: a storage unit 62 that stores physical object data indicating properties of the physical object; and a computation unit 61 that generates a hierarchical reduced-order matrix for a model of the physical object data. The computation unit 61 divides the overall structure into a plurality of partial structures, and calculates the reduced-order matrix using a unique mode and a static mode of each of the divided plurality of partial structures.

### TECHNICAL FIELD

The present invention relates particularly to a numerical analysis technique associated with model-based development. Targets of the model-based development include control devices such as fuel injection valves.

### BACKGROUND ART

Presently, model-based development may be used to develop systems and components. The model-based development may require model degeneration to reduce the costs of the numerical analysis. Non-patent literature 1 describes a conventional technology related to degeneration. According to non-patent literature 1, the following process is performed during the generation of the system matrix as a reduced-order matrix for a residual region. The system matrix is reduced to the residual region retaining the degree of freedom through the use of a static mode and an eigenmode in an internal region. The static mode is found by multiplying an inverse matrix of the internal region (eliminating the degree of freedom) and the stiffness of connection among an adjacent region, a boundary region, and the internal region.

### CITATION LIST

### Non-Patent Literature

Non-Patent Literature 1: Genki Yagawa and Yuji Aoyama. Finite element eigenvalue analysis—Large-scale parallel computing method. October 2001, pp. 102-106.

### SUMMARY OF INVENTION

### Technical Problem

According to non-patent literature 1, the entire structure is decomposed into partial structures for degeneration. A large-scale degree of freedom, if applied to each partial structure, requires a huge amount of calculation time and a large number of computer resources. For example, the calculation of the static mode requires inverse matrix calculation on the internal region. Inverse matrices for large-scale matrices may be required if a large-scale degree of freedom is applied to the model of the entire structure to be processed. Consequently, there is a need for a huge amount of calculation time and a large number of computer resources such as computer memory.

### Solution to Problem

To solve the above-described problem, the present invention provides a hierarchical reduced-order matrix generation device that generates hierarchical reduced-order matrices for numerical analysis of a physical object. The hierarchical reduced-order matrix generation device includes a storage portion and an operation portion. The storage portion stores physical object data representing characteristics of the physical object. The operation portion generates a hierarchical reduced-order matrix for a model of the physical object data. The operation portion divides an entire structure of the model of the physical object data into multiple partial structures. The operation portion calculates the reduced-order matrix by using an eigenmode and a static mode in each of the divided partial structures.

The present invention also includes a program for implementing functions of the hierarchical reduced-order matrix generation device and a medium to store the program. Furthermore, the invention includes a method of generating reduced-order matrices through the use of the hierarchical reduced-order matrix generation device.

### Advantageous Effects of Invention

The present invention can inhibit an increase in the calculation time and the use of computer resources for model degeneration.

### BRIEF DESCRIPTION OF DRAWINGS

FIG. 1 is a flowchart illustrating the Craig-Bampton method;

FIG. 2 is a flowchart illustrating the generation of a reduced-order matrix according to an embodiment of the present invention;

FIG. 3 is a flowchart illustrating a process of hierarchically dividing an entire structure including a boundary region and hierarchically combining partial structures;

FIG. 4 is a schematic diagram illustrating a process of dividing the entire structure into four partial structures each including the reduced-order matrix for the explanation of the embodiment as an example;

FIG. 5 is a schematic diagram illustrating a process of joining four partial structures, divided from the entire structure, each including the reduced-order matrix for the explanation of the embodiment as an example;

FIG. 6 is a function block diagram illustrating the hierarchical reduced-order matrix generation device according to the embodiment of the present invention; and

FIG. 7 is a hardware configuration diagram illustrating the hierarchical reduced-order matrix generation device according to the embodiment of the present invention.

### DESCRIPTION OF EMBODIMENT

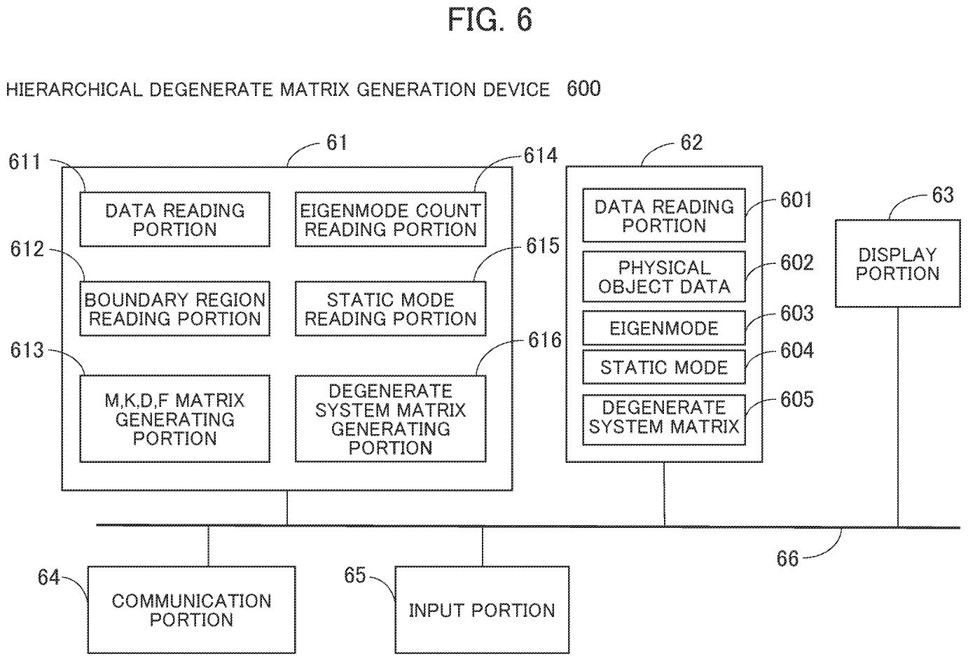

The description below explains an embodiment of the present invention by reference to the accompanying drawings. A so-called computer illustrated in FIG. 6 performs processes to be described later.

The description below explains the Craig-Bampton method as a prior art of the embodiment.

Conventional Technique

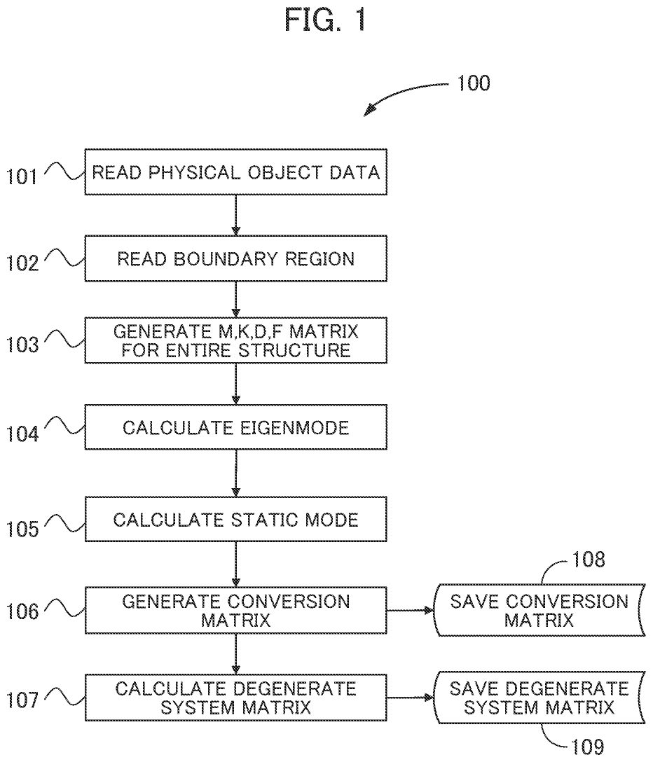

FIG. 1 is a flowchart illustrating the Craig-Bampton method. As described below, the Craig-Bampton method reduces the entire structure to the degree of freedom of a boundary region. In step 101, the process reads physical object data that describes the information about a physical object. Then, the process reads the boundary region that retains the degree of freedom. In step 103, the process generates a system matrix for the entire structure by using the data read in steps 101 and 102. In step 104, the process calculates an eigenmode for the generated system matrix under the condition of fixing the freedom of the boundary region. In step 104, the process calculates the static mode for the system matrix. The static mode is a product of the inverse matrix of an internal region to be eliminated and the connection stiffness matrix between the internal region and the boundary region to be retained. In step 106, the process generates a conversion matrix that generates reduced-order matrices. In step 108, the process saves the generated conversion matrix in the computer's external storage area. In step 107, the process calculates a reduced-order matrix for the conversion matrix. In step 109, the process saves the reduced-order matrix.

The description below explains steps 101 through 103 described above, concerning the increased computation time and the increased use of computer resources, as a problem of the present embodiment. Step 101 stores the physical object data in the computer's memory. Step 102 classifies the physical object data into internal region i and boundary region b. Step 103 generates a system matrix of mass matrix M, stiffness matrix K, damping matrix D, and load vector F based on the physical object data. As shown in equation 1, this system matrix is expressed by a motion equation of the entire structure. The purpose is to define a region retaining the degree of freedom and perform a degeneration calculation.

$$\begin{matrix}[ Math . 1 ] & \\ [ \begin{matrix}{M}_{i i} & {M}_{i b} \\ {M}_{i b}^{t} & {M}_{b b}\end{matrix} ] \{ \begin{matrix}{\ddot{u}}_{l} \\ {\ddot{u}}_{b}\end{matrix} \} + [ \begin{matrix}{D}_{i i} & {D}_{i b} \\ {D}_{i b}^{t} & {D}_{b b}\end{matrix} ] \{ \begin{matrix}{\dot{u}}_{l} \\ {\dot{u}}_{b}\end{matrix} \} + [ \begin{matrix}{K}_{i i} & {K}_{i b} \\ {K}_{i b}^{t} & {K}_{b b}\end{matrix} ] \{ \begin{matrix}{u}_{i} \\ {u}_{b}\end{matrix} \} = \{ \begin{matrix}{f}_{i} \\ {f}_{b}\end{matrix} \} & ( Math . 1 )\end{matrix}$$

Displacement u_{b} of the boundary region retaining the degree of freedom and displacement uᵢ of the internal region can be expressed as equation 2 below.

$$\begin{matrix}[ Math . 2 ] & \\ \{ \begin{matrix}{u}_{i} \\ {u}_{b}\end{matrix} \} = \{ \begin{matrix}[ {φ}_{i} ] \{ {ξ}_{i} \} + [ {G}_{i b} ] \{ {u}_{b} \} \\ {u}_{b}\end{matrix} \} = [ \begin{matrix}{ϕ}_{i} & {G}_{i b} \\ 0 & I\end{matrix} ] \{ \begin{matrix}{ξ}_{i} \\ {u}_{b}\end{matrix} \} & ( Math . 2 )\end{matrix}$$

As expressed in equation 3, static mode matrix G_{ib} is a vector represented by a product of the inverse matrix of the internal region to be eliminated and the connection stiffness matrix between the internal region and the boundary region to be retained.

Eigenmode matrix Φᵢ provides an eigenmode found by the eigenvalue calculation of equation 4.

[Math. 3]

G_{ib}=Kᵢᵢ⁻K_{ib} (Math 3)

[Math. 4]

{[Kᵢᵢ]−[ω²][Mᵢᵢ]}{x}=0 (Math. 4)

Conversion matrix T is expressed in equation 5. The reduced system matrix is calculated and generated by equations 6, 7, and 8.

$$\begin{matrix}[ Math . 5 ] & \\ T = [ \begin{matrix}{ϕ}_{i} & {G}_{i b} \\ 0 & I\end{matrix} ] & ( Math . 5 )\end{matrix}$$

$$\begin{matrix}[ Math . 6 ] & \\ \overline{M} = {[ \begin{matrix}{ϕ}_{i} & {G}_{i b} \\ 0 & I\end{matrix} ]}^{t} [ \begin{matrix}{M}_{i i} & {M}_{i b} \\ {M}_{i b}^{t} & {M}_{b b}\end{matrix} ] [ \begin{matrix}{ϕ}_{i} & {G}_{i b} \\ 0 & I\end{matrix} ] & ( Math . 6 )\end{matrix}$$

$$\begin{matrix}[ Math . 7 ] & \\ \overline{K} = {[ \begin{matrix}{ϕ}_{i} & {G}_{i b} \\ 0 & I\end{matrix} ]}^{t} [ \begin{matrix}{K}_{i i} & {K}_{i b} \\ {K}_{i b}^{t} & {K}_{b b}\end{matrix} ] [ \begin{matrix}{ϕ}_{i} & {G}_{i b} \\ 0 & I\end{matrix} ] & ( Math . 7 )\end{matrix}$$

$$\begin{matrix}[ Math . 8 ] & \\ \overline{D} = {[ \begin{matrix}{ϕ}_{i} & {G}_{i b} \\ 0 & I\end{matrix} ]}^{t} [ \begin{matrix}{D}_{i i} & {D}_{i b} \\ {D}_{i b}^{t} & {D}_{b b}\end{matrix} ] [ \begin{matrix}{ϕ}_{i} & {G}_{i b} \\ 0 & I\end{matrix} ] & ( Math . 8 )\end{matrix}$$

As above, the displacement of the internal region is expressed by the linear sum of the displacement of the boundary region and the eigenmode. The dimension of the motion equation is reduced to the sum of the number of eigenmodes and the degree of freedom of the boundary region.

However, if a large-scale degree of freedom is applied to all partial structures, the above-described process requires a large number of calculations and computer resources such as the computer memory capacity and the external storage capacity. As shown in equation 3, the inverse matrix of the internal region needs to be calculated to reduce the dimensions of the motion equation. A large-scale inverse matrix may be needed if the entire structure uses a large-scale degree of freedom. There is a need for a huge amount of computation time and a large number of computer resources.

In addition, the conversion matrix is required for the process of generating a reduced-order matrix from the entire structure and the process of restoring a response (such as displacement) for the entire structure from the calculation result of the reduced-order matrix. The conversion matrix mutually converts all system matrices and reduced-order system matrices. The size of the conversion matrix is the product of the degree of freedom of the entire structure and the boundary region. The conversion matrix provides a few nonzeros. There may be several millions of degrees of freedom if a large-scale degree of freedom is applied to all partial structures. The calculation using the conversion matrices requires a large number of computer resources and calculations.

Generating a Hierarchical Reduced-Order Matrix

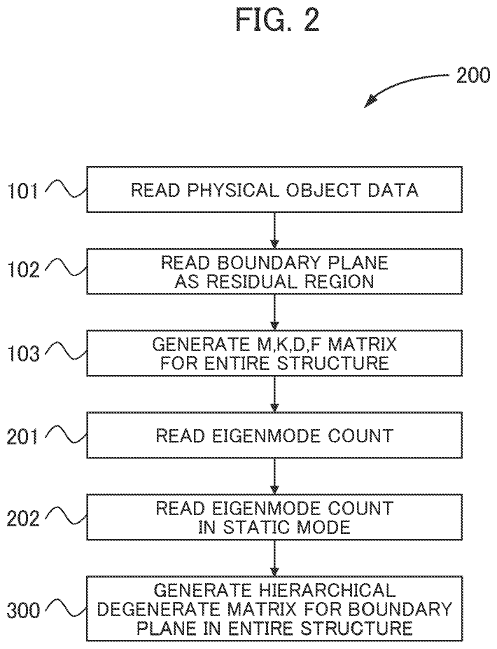

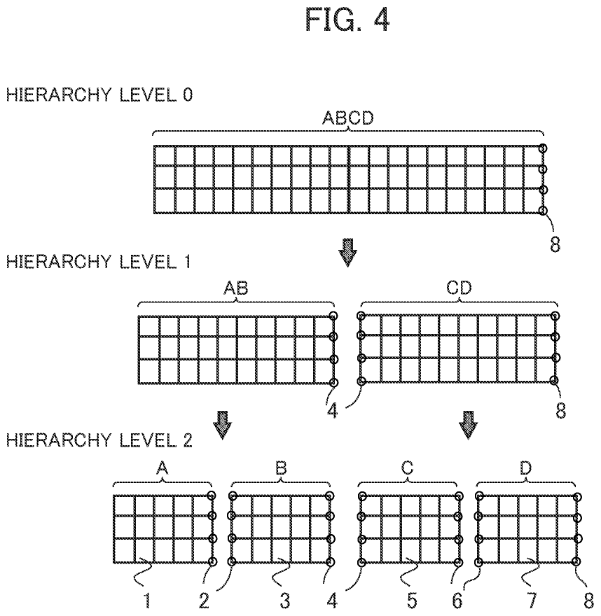

The description below explains a technique for generating the hierarchical reduced-order matrix according to the present embodiment to solve those problems. Specifically, FIGS. 2 through 4, 6, and 7 are referenced to illustrate a process of hierarchically dividing the entire structure to be processed into partial structures and hierarchically generating reduced-order system matrices. The entire structure represents a model of physical object data and is represented by hierarchical level 0 in FIG. 4.

FIG. 6 illustrates a hierarchical reduced-order matrix generation device 600 that generates a reduced-order matrix. FIG. 6 is a function block diagram illustrating the hierarchical reduced-order matrix generation device 600. The hierarchical reduced-order matrix generation device 600 includes an operation portion 61, a storage portion 62, a display portion 63, a communication portion 64, an input portion 65, and a connection portion 66 such as a bus. The operation portion 61 performs a process to hierarchically generate reduced-order system matrices. The operation portion 61 includes a data reading portion 611, a boundary region reading portion 612, an M, K, D, F matrix generating portion 613, an eigenmode count reading portion 614, a static mode reading portion 615, and a reduced-order matrix generating portion 616. These portions operate according to a reduced-order matrix generating program 601 stored in the storage portion 62. The storage portion 62 also stores physical object data 602, eigenmode 603, static mode 604, and reduced-order matrix 605. The contents of these will be described later. At least part of various information stored in the storage portion 62 may be stored in another storage device connected via the communication portion 64.

The display portion 63 displays the processing results of the operation portion 61 and information input via the input portion 65. The communication portion 64 connects with other devices such as computers via a network such as the Internet. The input portion 65 accepts inputs from users. The connection portion 66 connects the above-described portions.

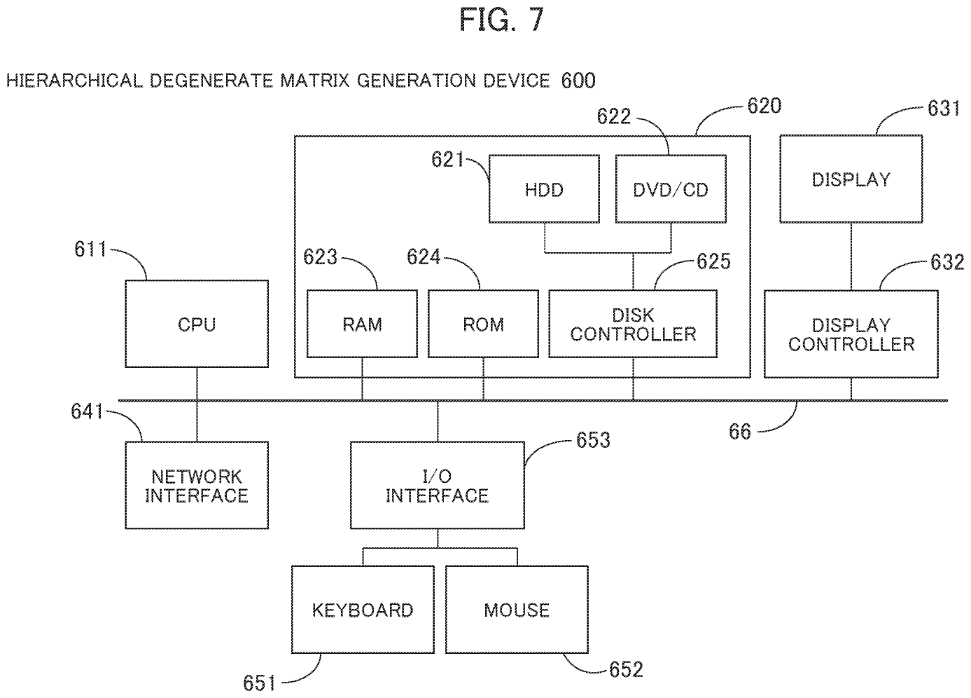

FIG. 7 is referenced to describe a hardware configuration of the hierarchical reduced-order matrix generation device 600. The hierarchical reduced-order matrix generation device 600 is embodied by a so-called computer. The hardware of the hierarchical reduced-order matrix generation device 600 is configured as a CPU 6110, a storage device 620, a display 631, a display controller 632, a network interface 641, a keyboard 651, a mouse 652, and an I/O interface 653.

These hardware components correspond to the function blocks in FIG. 6 as follows.

CPU 6110 . . . operation portion 61
Storage device 620 . . . storage portion 62
Display 631, display controller 632 . . . display portion 63
Network interface 641 . . . communication portion 64
Keyboard 651, mouse 652, I/O interface 653 . . . input portion 65

The storage device 620 includes RAM 623 and ROM 624 that store various information illustrated in FIG. 6 and are accessed from the CPU 6110. The storage device 620 includes a disk controller 625 that controls storage media such as HDD 621 and DVD/CD 622 and access to them. The storage media store the reduced-order matrix generating program 601 and various other information. The storage device 620 loads the reduced-order matrix generating program 601 to the ROM 610. RAM 608 is used as a working area.

The CPU 6110 accesses memory and performs processes according to the reduced-order matrix generating program 601. Details of the processes will be described later in detail by reference to FIGS. 2 through 5.

The display 631 displays various information under the control of the display controller 632. The network interface 641 is networked to other devices.

The keyboard 651 and the mouse 652 accept inputs from the user. The I/O interface 653 notifies the input contents to the CPU 6110, for example.

FIG. 2 is a flowchart 200 illustrating an example method that hierarchically divides an entire structure including the boundary region and hierarchically generates reduced-order system matrices. By reference to FIG. 2, the description below explains the whole process to generate reduced-order system matrices. The following description of the flowchart also references the function block diagram in FIG. 6.

In step 101, the data reading portion 611 reads physical object data. The data reading portion 611 reads the physical object data 602 stored in the storage portion 62. The physical object data 602 provides a model that represents the characteristics of a physical object as a target of model development. The physical object data contains the control characteristics of the controller and components. This step is the same process as step 101 in FIG. 1. The same applies to steps 102 and 103.

In step 102, the boundary region reading portion 612 reads the boundary region retaining the degree of freedom. This signifies decomposing the physical object data into internal region i and boundary region b. Internal region i does not contact with other models. Boundary region b contacts with other models.

In step 103, the M, K, D, F matrix generating portion 613 generates a system matrix for the entire structure by using the results of steps 101 and 102. As above, the process generates the system matrix of mass matrix M, stiffness matrix K, damping matrix D, and load vector F.

In step 201, the eigenmode count reading portion 614 reads an eigenmode count 603 stored in the storage portion 62.

In step 202, the static mode reading portion 615 reads an eigenmode count (static mode 604) of static mode.

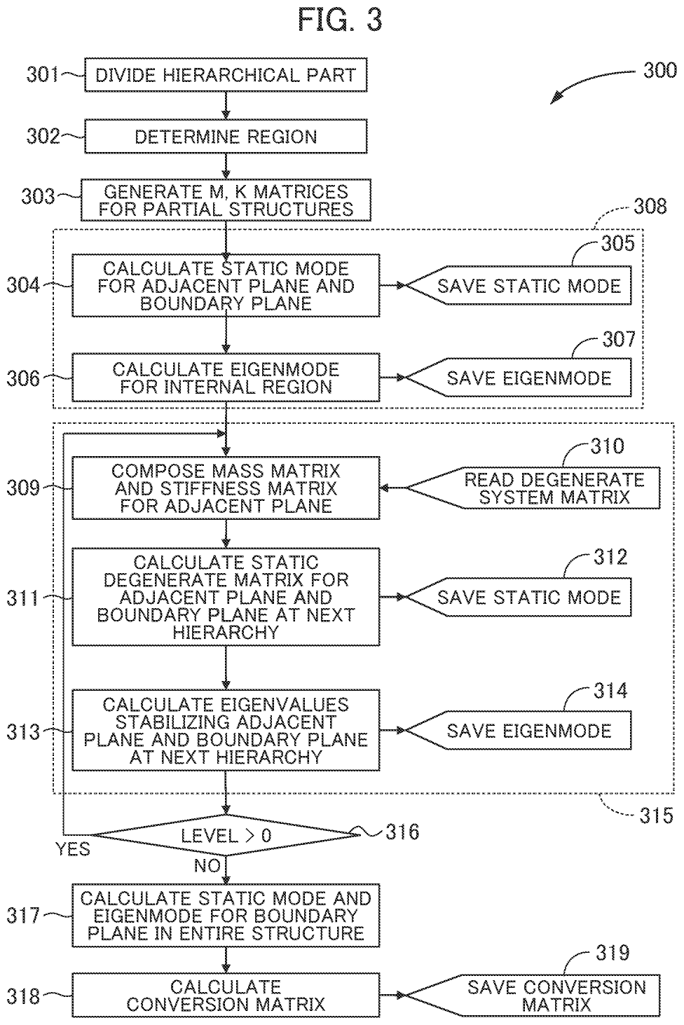

In step 300, the reduced-order matrix generating portion hierarchically generates the reduced-order system matrices by using the eigenmode count 603 and the static mode 604. The details of step 303 will be explained by reference to FIG. 3.

FIG. 3 is a flowchart detailing step 300.

In step 301, the reduced-order matrix generating portion 616 divides the entire structure corresponding to the physical object data into partial structures. To do this division, the reduced-order matrix generating portion 616 specifies hierarchy levels, namely, the number of divisions. For this purpose, the degree of freedom of the partial structure is used for information such as operation loads on the computer and available memory areas. This makes it possible to enable operations using an appropriate number of divisions and reduce the amount of operation and the amount of memory used.

The description below explains a specific example of division in this step by reference to FIG. 4.

This example divides the physical object data into four partial structures. The reduced-order matrix generating portion 616 divides the physical object data into four partial structures A, B, C, and D as hierarchy level 2. The layer to be divided is defined as a higher layer. The divided layer is defined as a lower layer. According to the example in FIG. 4, hierarchy level 0 corresponds to the highest hierarchy and hierarchy level 2 corresponds to the lowest hierarchy. The division into partial structures may be performed at once from hierarchy level 0 to hierarchy levels 1 and 2 or stepwise such as division into hierarchy level 1 and then into hierarchy level 2. The one-time division can improve the processing speed. The stepwise division can equalize loads.

In step 302, the reduced-order matrix generating portion 616 determines a partial region at each hierarchy level. Namely, it is determined whether each partial structure corresponds to an internal region, a boundary region, or an adjacent region. The internal region eliminates the degree of freedom. The boundary region retains the degree of freedom. The adjacent region is adjacently located between partial structures.

According to the example in FIG. 4, adjacent regions at hierarchy level 2 include an adjacent region 2 between partial structure A and partial structure B and an adjacent region 6 between partial structure C and partial structure D. Internal regions include an internal region 1 of partial structure A, an internal region 3 of partial structure B, an internal region 5 of partial structure C, and an internal region 7 of partial structure D. The boundary region is defined as a boundary region 8 in partial structure D. The reduced-order matrix generating portion 616 stores these pieces of information in the storage portion 62.

The reduced-order matrix generating portion 616 identifies an adjacent region 4, as an adjacent region of hierarchy level 1, between partial structure AB and partial structure CD. The reduced-order matrix generating portion 616 identifies the boundary region 8 as a boundary region. The reduced-order matrix generating portion 616 also stores these pieces of information in the storage portion 62. Finally, the reduced-order matrix generating portion 616 identifies the information about the boundary region 8 of partial structure ABCD as a boundary region at hierarchy level 0. The reduced-order matrix generating portion 616 also stores this information in the storage portion 62.

In step 303, the reduced-order matrix generating portion 616 generates mass matrix M and stiffness matrix K for the entire structure according to equations 9 and 10. Each partial structure belongs to any of partial structures A, B, C, and D. In equations 9 and 10, the lower right subscript indicates the matrix number of the entire structure. The upper right subscript indicates the corresponding partial structure.

$$[ Math . 9 ] \\ ( Math . 9 ) \\ M = [ \begin{matrix}{M}_{11}^{A} & {M}_{12}^{A} & 0 & 0 & 0 & 0 & 0 & 0 \\ {M}_{21}^{A} & {M}_{22}^{A} + {M}_{22}^{B} & 0 & 0 & 0 & 0 & 0 & 0 \\ 0 & {M}_{32}^{B} & {M}_{33}^{B} & {M}_{34}^{B} & 0 & 0 & 0 & 0 \\ 0 & 0 & {M}_{43}^{B} & {M}_{44}^{B} + {M}_{44}^{C} & {M}_{45}^{C} & 0 & 0 & 0 \\ 0 & 0 & 0 & {M}_{54}^{C} & {M}_{55} & {M}_{67}^{D} & 0 & 0 \\ 0 & 0 & 0 & 0 & {M}_{65}^{D} & {M}_{66}^{C} + {M}_{66}^{D} & {M}_{67}^{D} & 0 \\ 0 & 0 & 0 & 0 & 0 & {M}_{76}^{D} & {M}_{77}^{D} & {M}_{78}^{D} \\ 0 & 0 & 0 & 0 & 0 & 0 & {M}_{87}^{D} & {M}_{88}^{D}\end{matrix} ]$$

$$[ Math . 10 ] \\ ( Math . 10 ) \\ K = [ \begin{matrix}{K}_{11}^{A} & {K}_{12}^{A} & 0 & 0 & 0 & 0 & 0 & 0 \\ {K}_{21}^{A} & {K}_{22}^{A} + {K}_{22}^{B} & 0 & 0 & 0 & 0 & 0 & 0 \\ 0 & {K}_{32}^{B} & {K}_{33}^{B} & {K}_{34}^{B} & 0 & 0 & 0 & 0 \\ 0 & 0 & {K}_{43}^{B} & {K}_{44}^{B} + {K}_{44}^{C} & {K}_{45}^{C} & 0 & 0 & 0 \\ 0 & 0 & 0 & {K}_{54}^{C} & {K}_{55} & {K}_{67}^{D} & 0 & 0 \\ 0 & 0 & 0 & 0 & {K}_{65}^{D} & {K}_{66}^{C} + {K}_{66}^{D} & {K}_{67}^{D} & 0 \\ 0 & 0 & 0 & 0 & 0 & {K}_{76}^{D} & {K}_{77}^{D} & {K}_{78}^{D} \\ 0 & 0 & 0 & 0 & 0 & 0 & {K}_{87}^{D} & {K}_{88}^{D}\end{matrix} ]$$

The reduced-order matrix generating portion 616 calculates a system matrix for each partial structure. The reduced-order matrix generating portion 616 divides the physical object into infinitely many and acquires corresponding nodes and elements. The reduced-order matrix generating portion 616 calculates the system matrix for the partial structure based on the superposition principle through the use of material physical property values given the system matrices used in the numerical analysis. Material physical property values may be replaced by other properties. Specifically, the reduced-order matrix generating portion 616 calculates the system matrix for partial structure A according to equations 11 and 12.

$$\begin{matrix}[ Math . 11 ] & \\ {M}_{A} = [ \begin{matrix}{M}_{11}^{A} & {M}_{12}^{A} \\ {M}_{21}^{A} & {M}_{22}^{A}\end{matrix} ] & ( Math . 11 )\end{matrix}$$

$$\begin{matrix}[ Math . 12 ] & \\ {K}_{A} = [ \begin{matrix}{K}_{11}^{A} & {K}_{12}^{A} \\ {K}_{21}^{A} & {K}_{22}^{A}\end{matrix} ] & ( Math . 12 )\end{matrix}$$

At step 308, the reduced-order matrix generating portion 616 performs a degeneration calculation on each partial structure. For example, in step 203, partial structure A is classified into the internal region 1 and the adjacent region 2 adjacent to partial structure B in the layer higher than the current layer. Then, the reduced-order matrix generating portion 616 performs a reduced-order calculation on the adjacent region 2 and the internal region 1 based on only the degree of freedom of the adjacent region 2.

Step 308 includes steps 304 through 307 and is described in detail below by taking partial structure A as an example.

In step 304, the reduced-order matrix generating portion 616 calculates static modes of the adjacent plane and the boundary plane for each partial structure. Specifically, the reduced-order matrix generating portion 616 calculates static modes of the adjacent region and the boundary region to generate a system matrix for the adjacent region 2 of the upper layer higher than partial structure A. In step 305, the reduced-order matrix generating portion 616 stores the calculated static mode in the storage portion 62.

At step 306, the reduced-order matrix generating portion 616 calculates an eigenmode of the internal region. The reduced-order matrix generating portion 616 calculates an eigenmode by performing eigenvalue decomposition on the internal region of partial structure A as described above. In step 307, the reduced-order matrix generating portion 616 stores the calculated eigenmode in the storage portion 62.

The reduced-order matrix generating portion 616 calculates a reduced-order matrix in partial structure A by using equation 13 to yield equations 14 and 15.

$$\begin{matrix}[ Math . 13 ] & \\ {T}_{A} = [ \begin{matrix}{ϕ}_{1}^{A} & {ψ}_{2}^{A} \\ 0 & I\end{matrix} ] & ( Math . 13 )\end{matrix}$$

$$\begin{matrix}[ Math . 14 ] & \\ \overline{{M}_{A}} = [ \begin{matrix}{I}_{11}^{A} & {μ}_{12}^{A} \\ {μ}_{21}^{A} & \overline{{K}_{22}^{A}}\end{matrix} ] & ( Math . 14 )\end{matrix}$$

$$\begin{matrix}[ Math . 15 ] & \\ \overline{{K}_{A}} = [ \begin{matrix}{Λ}_{11}^{A} & 0 \\ 0 & \overline{{K}_{22}^{A}}\end{matrix} ] & ( Math . 15 )\end{matrix}$$

The reduced-order matrix generating portion 616 calculates reduced-order system matrices for partial structures B, C, and D according to the similar procedure.

The reduced-order matrix generating portion 616 yields equations 16 and 17 as reduced-order system matrices for partial structure B. Partial structure B includes the internal region 3, the adjacent region 2 at hierarchy level 1, and the adjacent region 4 at hierarchy level 0. The reduced-order matrix generating portion 616 reduces the degree of freedom to ensure only the adjacent region 2 at hierarchy level 1 and the adjacent region 4 at hierarchy level 0. The reduced-order matrix generating portion 616 yields equation 18 as a conversion matrix. The reduced-order matrix generating portion 616 calculates a reduced-order matrix in partial structure B by using equation 18 to yield equations 19 and 20.

$$\begin{matrix}[ Math . 16 ] & \\ {M}_{B} = [ \begin{matrix}{M}_{22}^{B} & {M}_{23}^{B} & 0 \\ {M}_{32}^{B} & {M}_{33}^{B} & {M}_{34}^{B} \\ 0 & {M}_{43}^{B} & {M}_{44}^{B}\end{matrix} ] & ( Math . 16 )\end{matrix}$$

$$\begin{matrix}[ Math . 17 ] & \\ {K}_{B} = [ \begin{matrix}{K}_{22}^{B} & {K}_{23}^{B} & 0 \\ {K}_{32}^{B} & {K}_{33}^{B} & {K}_{34}^{B} \\ 0 & {K}_{43}^{B} & {K}_{44}^{B}\end{matrix} ] & ( Math . 17 )\end{matrix}$$

$$\begin{matrix}[ Math . 18 ] & \\ {T}_{B} = [ \begin{matrix}I & 0 & 0 \\ {ψ}_{2}^{B} & {ϕ}_{2}^{B} & {ψ}_{4}^{B} \\ 0 & 0 & I\end{matrix} ] & ( Math . 18 )\end{matrix}$$

$$\begin{matrix}[ Math . 19 ] & \\ \overline{{M}_{B}} = [ \begin{matrix}\overline{{M}_{22}^{B}} & {μ}_{12}^{B} & {μ}_{12}^{A} \\ {μ}_{12}^{B} & {I}_{33}^{B} & {μ}_{12}^{A} \\ {μ}_{12}^{A} & {μ}_{12}^{A} & \overline{{M}_{44}^{B}}\end{matrix} ] & ( Math . 19 )\end{matrix}$$

$$\begin{matrix}[ Math . 20 ] & \\ \overline{{K}_{B}} = [ \begin{matrix}\overline{{K}_{22}^{B}} & 0 & \overline{{K}_{24}^{B}} \\ 0 & {Λ}_{33}^{B} & 0 \\ \overline{{K}_{42}^{B}} & 0 & \overline{{K}_{44}^{B}}\end{matrix} ] & ( Math . 20 )\end{matrix}$$

The reduced-order matrix generating portion 616 yields equations 21 and 22 as system matrices for partial structure C. Partial structure C includes the internal region 5, the adjacent region 6 between partial structures C and D at hierarchy level 1, and the adjacent region 4 at hierarchy level 0. The reduced-order matrix generating portion 616 reduces the degree of freedom to ensure only the adjacent regions 6 and 4 at hierarchy levels 1 and 0. The reduced-order matrix generating portion 616 yields equation 23 as a conversion matrix. The reduced-order matrix generating portion 616 calculates a reduced-order matrix in partial structure C by using equation 23 to yield equations 24 and 25.

$$\begin{matrix}[ Math . 21 ] & \\ {M}_{C} = [ \begin{matrix}{M}_{44}^{C} & {M}_{45}^{C} & 0 \\ {M}_{54}^{C} & {M}_{55}^{C} & {M}_{56}^{C} \\ 0 & {M}_{65}^{C} & {M}_{66}^{C}\end{matrix} ] & ( Math . 21 )\end{matrix}$$

$$\begin{matrix}[ Math . 22 ] & \\ {K}_{C} = [ \begin{matrix}{K}_{44}^{C} & {K}_{45}^{C} & 0 \\ {K}_{54}^{C} & {K}_{55}^{C} & {K}_{56}^{C} \\ 0 & {K}_{65}^{C} & {K}_{66}^{C}\end{matrix} ] & ( Math . 22 )\end{matrix}$$

$$\begin{matrix}[ Math . 23 ] & \\ {T}_{C} = [ \begin{matrix}I & 0 & 0 \\ {ψ}_{4}^{C} & {ϕ}_{5}^{C} & {ψ}_{6}^{C} \\ 0 & 0 & I\end{matrix} ] & ( Math . 23 )\end{matrix}$$

$$\begin{matrix}[ Math . 24 ] & \\ \overline{{M}_{C}} = [ \begin{matrix}\overline{{M}_{44}^{C}} & {μ}_{45}^{C} & {μ}_{45}^{C} \\ {μ}_{54}^{C} & {I}_{55}^{C} & {μ}_{56}^{C} \\ {μ}_{64}^{C} & {μ}_{65}^{C} & \overline{{M}_{66}^{C}}\end{matrix} ] & ( Math . 24 )\end{matrix}$$

$$\begin{matrix}[ Math . 25 ] & \\ \overline{{K}_{C}} = [ \begin{matrix}\overline{{K}_{44}^{C}} & 0 & \overline{{K}_{45}^{C}} \\ 0 & {Λ}_{55}^{C} & 0 \\ \overline{{K}_{64}^{C}} & 0 & \overline{{K}_{66}^{C}}\end{matrix} ] & ( Math . 25 )\end{matrix}$$

The reduced-order matrix generating portion 616 yields equations 26 and 27 as system matrices for partial structure D. Partial structure D includes the internal region 7, the adjacent region 6 at hierarchy level 1, and the boundary region 8. The reduced-order matrix generating portion 616 reduces the degree of freedom to ensure only the adjacent region 6 at hierarchy level 1 as the higher level and the boundary region 8. The reduced-order matrix generating portion 616 yields equation 28 as a conversion matrix. The reduced-order matrix generating portion 616 calculates a reduced-order matrix in partial structure D by using equation 28 to yield equations 29 and 30.

$$\begin{matrix}[ Math . 26 ] & \\ {M}_{D} = [ \begin{matrix}{M}_{66}^{D} & {M}_{66}^{D} & 0 \\ {M}_{67}^{D} & {M}_{67}^{D} & {M}_{78}^{D} \\ 0 & {M}_{87}^{D} & {M}_{88}^{D}\end{matrix} ] & ( Math . 26 )\end{matrix}$$

$$\begin{matrix}[ Math . 27 ] & \\ {K}_{D} = [ \begin{matrix}{K}_{66}^{D} & {K}_{67}^{D} & 0 \\ {K}_{76}^{D} & {K}_{77}^{D} & {K}_{78}^{D} \\ 0 & {K}_{87}^{D} & {K}_{88}^{D}\end{matrix} ] & ( Math . 27 )\end{matrix}$$

$$\begin{matrix}[ Math . 28 ] & \\ {T}_{D} = [ \begin{matrix}I & 0 & 0 \\ {ψ}_{6}^{D} & {ϕ}_{7}^{D} & {ψ}_{8}^{D} \\ 0 & 0 & I\end{matrix} ] & ( Math . 28 )\end{matrix}$$

$$\begin{matrix}[ Math . 29 ] & \\ \overline{{M}_{D}} = [ \begin{matrix}\overline{{M}_{66}^{D}} & {μ}_{67}^{D} & {μ}_{68}^{D} \\ {μ}_{76}^{D} & {I}_{77}^{D} & {μ}_{78}^{D} \\ {μ}_{86}^{D} & {μ}_{87}^{D} & \overline{{M}_{88}^{D}}\end{matrix} ] & ( Math . 29 )\end{matrix}$$

$$\begin{matrix}[ Math . 30 ] & \\ \overline{{K}_{D}} = [ \begin{matrix}\overline{{K}_{66}^{D}} & 0 & \overline{{K}_{68}^{D}} \\ 0 & {Λ}_{77}^{D} & 0 \\ \overline{{K}_{86}^{D}} & 0 & \overline{{K}_{88}^{D}}\end{matrix} ] & ( Math . 30 )\end{matrix}$$

The reduced-order matrix generating portion 616 also performs steps 304 and 305 during the operations on the partial structures B, C, and D.

As above, each divided partial structure can ensure the degree of freedom allowed for only the adjacent region and the boundary region. The entire structure is divided into partial structures, making it possible to reduce computer resources and the amount of calculation. The calculation of partial structures can be distributed to multiple processors (CPU 6110) as follows. A division method is determined as far as possible to equalize the product of the degree of freedom for the partial structure and the sum of the boundary region and the adjacent region. Consequently, it is possible to distribute computation loads and computer resources of each CPU 6110, equalize the time required of each processor for calculation, and decrease the wait time required of each CPU for processing.

Joining Partial Structures

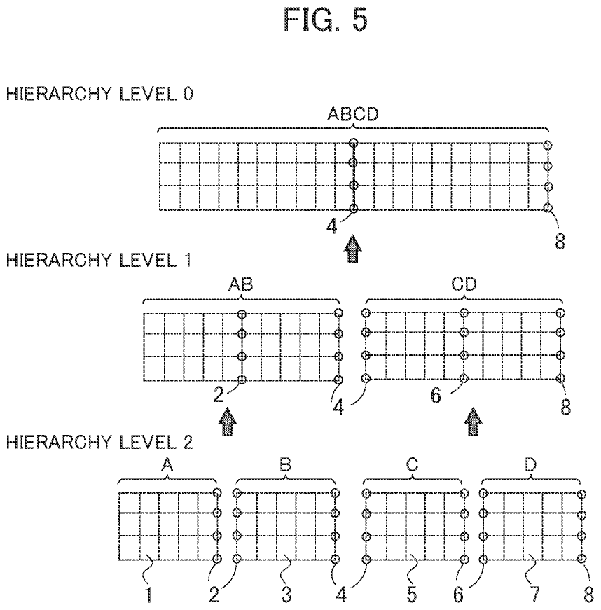

By reference to FIGS. 3 and 5, the description below explains a method of joining partial structures to the entire structure according to the present embodiment. The present embodiment enables joining based on a physical coordinate system because each partial structure retains the degree of freedom of the adjacent region.

The method of joining to the entire structure is performed in step 315 of FIG. 3. In step 309 of step 315, the reduced-order matrix generating portion 616 assembles (joins) the adjacent plane mass matrix and stiffness matrix in each partial structure. Specifically, the reduced-order matrix generating portion 616 uses the superposition principle. For example, the following process is performed to join partial structure A and partial structure B in FIG. 5. The reduced-order matrix generating portion 616 joins the reduced-order mass matrix and the reduced-order stiffness matrix in partial structures A and B according to equations 32 and 33.

To perform step 309, the reduced-order matrix generating portion 616 reads a reduced-order matrix for partial structures A and B from the storage portion 62 in step 310. This reduced-order matrix is expressed in equation 31.

$$\begin{matrix}[ Math . 31 ] & \\ {M}_{AB} = [ \begin{matrix}{I}_{11} & {μ}_{12}^{A} & 0 & 0 \\ {μ}_{21}^{A} & \overline{{M}_{22}^{A}} + \overline{{M}_{22}^{B}} & {μ}_{23}^{B} & {μ}_{24}^{B} \\ 0 & {μ}_{32}^{B} & I & {μ}_{34}^{B} \\ 0 & {μ}_{42}^{B} & {μ}_{43}^{B} & \overline{{M}_{44}^{B}}\end{matrix} ] & ( Math . 31 )\end{matrix}$$

$$\begin{matrix}[ Math . 32 ] & \\ {K}_{AB} = [ \begin{matrix}{Λ}_{11}^{A} & 0 & 0 & 0 \\ 0 & \overline{{K}_{22}^{A}} + \overline{{K}_{22}^{B}} & 0 & \overline{{K}_{24}^{B}} \\ 0 & 0 & {Λ}_{33}^{B} & 0 \\ 0 & \overline{{K}_{42}^{B}} & 0 & \overline{{K}_{44}^{B}}\end{matrix} ] & ( Math . 32 )\end{matrix}$$

$$\begin{matrix}[ Math . 33 ] & \\ {T}_{A B} = [ \begin{matrix}{ϕ}_{1}^{A B} & 0 & 0 & 0 \\ 0 & {ϕ}_{2}^{AB} & 0 & {ψ}_{24}^{AB} \\ 0 & 0 & {ϕ}_{3}^{AB} & 0 \\ 0 & 0 & 0 & I\end{matrix} ] & ( Math . 33 )\end{matrix}$$

In step 311, the reduced-order matrix generating portion 616 calculates a static reduced-order matrix. Suppose partial structure AB is joined in step 309. Partial structure AB is joined while including the adjacent region 4 at hierarchy level 0. Therefore, the adjacent region 4 joins partial structures A and B at hierarchy level 0. As a preliminary step, the reduced-order matrix generating portion 616 reduces the degree of freedom to be only applicable to the adjacent region 4 at hierarchy level 0. The reduced-order matrix generating portion 616 calculates a static reduced-order conversion matrix, shown in equation 33, for the adjacent plane and the boundary plane at the next layer. At step 312, the reduced-order matrix generating portion 616 stores the static mode, identified by the calculated static reduced-order conversion matrix, in the storage portion 62.

In step 313, the reduced-order matrix generating portion 616 uses these conversion matrices to calculate a reduced-order mass matrix and a reduced-order stiffness matrix and yield equations 34 and 35. Namely, the reduced-order matrix generating portion 616 calculates an eigenvalue under the condition of fixing the adjacent plane and the boundary plane at the next layer. At step 314, the reduced-order matrix generating portion 616 stores the calculated eigenvalue in the storage portion 62.

$$\begin{matrix}[ Math . 34 ] & \\ \overline{{M}_{AB}} = [ \begin{matrix}{I}_{11}^{AB} & {μ}_{12}^{AB} & {μ}_{13}^{AB} & {μ}_{14}^{AB} \\ {μ}_{21}^{AB} & {I}_{22}^{AB} & {μ}_{23}^{AB} & {μ}_{24}^{AB} \\ {μ}_{31}^{AB} & {μ}_{32}^{AB} & {I}_{33}^{AB} & {μ}_{34}^{AB} \\ {μ}_{41}^{AB} & {μ}_{42}^{AB} & {μ}_{43}^{AB} & \overline{{M}_{44}^{AB}}\end{matrix} ] & ( Math . 34 )\end{matrix}$$

$$\begin{matrix}[ Math . 35 ] & \\ \overline{{K}_{A B}} = [ \begin{matrix}{Λ}_{11}^{AB} & 0 & 0 & 0 \\ 0 & {Λ}_{22}^{AB} & 0 & 0 \\ 0 & 0 & {Λ}_{33}^{AB} & 0 \\ 0 & 0 & 0 & \overline{{K}_{44}^{AB}}\end{matrix} ] & ( Math . 35 )\end{matrix}$$

The description below explains an example of joining partial structures C and D illustrated in FIG. 5. At step 309, the reduced-order matrix generating portion 616 joins the reduced-order mass matrix and the reduced-order stiffness matrix in partial structures C and D. The reduced-order matrix generating portion 616 also uses the superposition principle to perform the join according to equations 36 and 37.

$$\begin{matrix}[ Math . 36 ] & \\ {M}_{CD} = [ \begin{matrix}\overline{{M}_{44}^{C}} & {μ}_{45}^{C} & {μ}_{46}^{B} & 0 & 0 \\ {μ}_{54}^{C} & I & {μ}_{56}^{B} & 0 & 0 \\ {μ}_{64}^{C} & {μ}_{65}^{C} & \overline{{M}_{66}^{C}} + \overline{{M}_{66}^{D}} & {μ}_{67}^{D} & {μ}_{68}^{D} \\ 0 & 0 & {μ}_{76}^{D} & I & {μ}_{78}^{D} \\ 0 & 0 & {μ}_{86}^{D} & {μ}_{87}^{D} & {M}_{88}^{D}\end{matrix} ] & ( Math . 36 )\end{matrix}$$

$$\begin{matrix}[ Math . 37 ] & \\ {K}_{CD} = [ \begin{matrix}\overline{{K}_{44}^{C}} & 0 & \overline{{K}_{46}^{C}} & 0 & 0 \\ 0 & {Λ}_{55}^{C} & 0 & 0 & 0 \\ \overline{{K}_{64}^{C}} & 0 & \overline{{K}_{66}^{C}} + \overline{{K}_{66}^{D}} & 0 & \overline{{K}_{68}^{D}} \\ 0 & 0 & 0 & {Λ}_{77}^{D} & 0 \\ 0 & 0 & \overline{{K}_{86}^{D}} & 0 & \overline{{K}_{88}^{D}}\end{matrix} ] & ( Math . 37 )\end{matrix}$$

In step 311, the reduced-order matrix generating portion 616 calculates a static reduced-order matrix. The joined partial structure is defined as partial structure CD. The partial structure CD is joined with the inclusion of the adjacent region 4 and the boundary region 8 according to the above-described analysis. The reduced-order matrix generating portion 616 reduces orders so that the degree of freedom is allowed for only the boundary region 8 to generate reduced-order system matrices for the adjacent region 4 and the entire structure and yield the conversion matrix shown in equation 38.

In step 313, the reduced-order matrix generating portion 616 uses the conversion matrix to calculate a reduced-order mass matrix and a reduced-order stiffness matrix and yields equations 39 and 40.

$$\begin{matrix}[ Math . 38 ] & \\ {T}_{CD} = [ \begin{matrix}I & 0 & 0 & 0 & 0 \\ 0 & {ϕ}_{5}^{CD} & 0 & 0 & 0 \\ {ψ}_{64}^{CD} & 0 & {ϕ}_{6}^{CD} & 0 & {ψ}_{68}^{CD} \\ 0 & 0 & 0 & {ϕ}_{7}^{CD} & 0 \\ 0 & 0 & 0 & 0 & I\end{matrix} ] & ( Math . 38 )\end{matrix}$$

$$\begin{matrix}[ Math . 39 ] & \\ \overline{{M}_{CD}} = [ \begin{matrix}\overline{{M}_{44}^{CD}} & {μ}_{45}^{CD} & {μ}_{46}^{CD} & {μ}_{47}^{CD} & {μ}_{48}^{CD} \\ {μ}_{54}^{CD} & {I}_{55}^{CD} & {μ}_{56}^{CD} & {μ}_{57}^{CD} & {μ}_{58}^{CD} \\ {μ}_{64}^{CD} & {μ}_{65}^{CD} & {I}_{66}^{CD} & {μ}_{67}^{CD} & {μ}_{68}^{CD} \\ {μ}_{74}^{CD} & {μ}_{75}^{CD} & {μ}_{76}^{CD} & {I}_{77}^{CD} & {μ}_{78}^{CD} \\ {μ}_{84}^{CD} & {μ}_{85}^{CD} & {μ}_{86}^{CD} & {μ}_{87}^{CD} & {I}_{88}^{CD}\end{matrix} ] & ( Math . 39 )\end{matrix}$$

$$\begin{matrix}[ Math . 40 ] & \\ \overline{{K}_{CD}} = [ \begin{matrix}\overline{{K}_{44}^{CD}} & 0 & 0 & 0 & \overline{{K}_{48}^{CD}} \\ 0 & {Λ}_{55}^{CD} & 0 & 0 & 0 \\ 0 & 0 & {Λ}_{66}^{CD} & 0 & 0 \\ 0 & 0 & 0 & {Λ}_{77}^{CD} & 0 \\ \overline{{K}_{84}^{CD}} & 0 & 0 & 0 & \overline{{K}_{88}^{CD}}\end{matrix} ] & ( Math . 40 )\end{matrix}$$

The description below explains an example of joining partial structures AB and CD illustrated in FIG. 5. In step 309, the reduced-order matrix generating portion 616 joins the reduced-order mass matrix and the reduced-order stiffness matrix in partial structures AB and CD. The reduced-order matrix generating portion 616 also uses the superposition principle to perform the join according to equations 41 and 42.

$$\begin{matrix}[ Math . 41 ] & \\ {K}_{ABCD} = [ \begin{matrix}{Λ}_{11}^{AB} & 0 & 0 & 0 & 0 & 0 & 0 & \overline{{K}_{48}^{CD}} \\ 0 & {Λ}_{22}^{AB} & 0 & 0 & 0 & 0 & 0 & 0 \\ 0 & 0 & {Λ}_{33}^{AB} & 0 & 0 & 0 & 0 & 0 \\ 0 & 0 & 0 & \overline{{K}_{44}^{AB}} + \overline{{K}_{44}^{CD}} & 0 & 0 & 0 & 0 \\ 0 & 0 & 0 & 0 & {Λ}_{55}^{CD} & 0 & 0 & 0 \\ 0 & 0 & 0 & 0 & 0 & {Λ}_{66}^{CD} & 0 & 0 \\ 0 & 0 & 0 & 0 & 0 & 0 & {Λ}_{77}^{CD} & 0 \\ 0 & 0 & 0 & \overline{{K}_{84}^{CD}} & 0 & 0 & 0 & \overline{{K}_{88}^{CD}}\end{matrix} ] & ( Math . 41 )\end{matrix}$$

$$\begin{matrix}[ Math . 42 ] & \\ {M}_{ABCD} = [ \begin{matrix}{I}_{11}^{AB} & {μ}_{12}^{AB} & {μ}_{13}^{AB} & {μ}_{14}^{AB} & 0 & 0 & 0 & 0 \\ {μ}_{21}^{AB} & {I}_{22}^{AB} & {μ}_{23}^{AB} & {μ}_{24}^{AB} & 0 & 0 & 0 & 0 \\ {μ}_{31}^{AB} & {μ}_{32}^{AB} & {I}_{33}^{AB} & {μ}_{34}^{AB} & 0 & 0 & 0 & 0 \\ {μ}_{41}^{AB} & {μ}_{42}^{AB} & {μ}_{43}^{AB} & \overline{{M}_{44}^{AB}} + \overline{{M}_{44}^{CD}} & {μ}_{45}^{CD} & {μ}_{46}^{CD} & {μ}_{47}^{CD} & {μ}_{48}^{CD} \\ 0 & 0 & 0 & {μ}_{54}^{CD} & {I}_{55}^{CD} & {μ}_{56}^{CD} & {μ}_{57}^{CD} & {μ}_{58}^{CD} \\ 0 & 0 & 0 & {μ}_{64}^{CD} & {μ}_{65}^{CD} & {I}_{66}^{CD} & {μ}_{67}^{CD} & {μ}_{68}^{CD} \\ 0 & 0 & 0 & {μ}_{74}^{CD} & {μ}_{75}^{CD} & {μ}_{76}^{CD} & {I}_{77}^{CD} & {μ}_{78}^{CD} \\ 0 & 0 & 0 & {μ}_{84}^{CD} & {μ}_{85}^{CD} & {μ}_{86}^{CD} & {μ}_{87}^{CD} & \overline{{M}_{88}^{CD}}\end{matrix} ] & ( Math . 42 )\end{matrix}$$

In step 311, the reduced-order matrix generating portion 616 calculates a static reduced-order matrix. The joined partial structure is defined as partial structure ABCD. The partial structure ABCD includes the boundary region 8 needed to generate a reduced-order matrix for the entire structure. The reduced-order matrix generating portion 616 reduces orders so that the degree of freedom is allowed for only the boundary region 8 to yield the conversion matrix shown in equation 43. In step 315, the reduced-order matrix generating portion 616 calculates the conversion matrix by reducing orders and joining partial structures in order from the lower layer to the higher layer.

In step 313, the reduced-order matrix generating portion 616 uses the conversion matrix to calculate a reduced-order mass matrix and a reduced-order stiffness matrix and yield equations 44 and 45.

$$[ Math . 43 ] \\ ( Math . 43 ) \\ {T}_{ABCD} = \\ [ \begin{matrix}{ϕ}_{1}^{ABCD} & 0 & 0 & 0 & 0 & 0 & 0 & 0 \\ 0 & {ϕ}_{2}^{ABCD} & 0 & 0 & 0 & 0 & 0 & 0 \\ 0 & 0 & {ϕ}_{3}^{ABCD} & 0 & 0 & 0 & 0 & 0 \\ 0 & 0 & 0 & {ϕ}_{4}^{ABCD} & 0 & 0 & 0 & {ψ}_{48}^{ABCD} \\ 0 & 0 & 0 & 0 & {ϕ}_{5}^{ABCD} & 0 & 0 & 0 \\ 0 & 0 & 0 & 0 & 0 & {ϕ}_{6}^{ABCD} & 0 & 0 \\ 0 & 0 & 0 & 0 & 0 & 0 & {ϕ}_{7}^{ABCD} & 0 \\ 0 & 0 & 0 & 0 & 0 & 0 & 0 & I\end{matrix} ]$$

$$[ Math . 44 ] \\ ( Math . 44 ) \\ \overline{{K}_{ABCD}} = \\ [ \begin{matrix}{Λ}_{11}^{ABCD} & 0 & 0 & 0 & 0 & 0 & 0 & 0 \\ 0 & {Λ}_{22}^{ABCD} & 0 & 0 & 0 & 0 & 0 & 0 \\ 0 & 0 & {Λ}_{33}^{ABCD} & 0 & 0 & 0 & 0 & 0 \\ 0 & 0 & 0 & {Λ}_{44}^{ABCD} & 0 & 0 & 0 & 0 \\ 0 & 0 & 0 & 0 & {Λ}_{55}^{ABCD} & 0 & 0 & 0 \\ 0 & 0 & 0 & 0 & 0 & {Λ}_{66}^{ABCD} & 0 & 0 \\ 0 & 0 & 0 & 0 & 0 & 0 & {Λ}_{77}^{ABCD} & 0 \\ 0 & 0 & 0 & 0 & 0 & 0 & 0 & \overline{{K}_{88}^{ABCD}}\end{matrix} ]$$

$$[ Math . 45 ] \\ ( Math . 45 ) \\ \overline{{M}_{ABCD}} = \\ [ \begin{matrix}{I}_{11}^{ABCD} & {μ}_{12}^{ABCD} & {μ}_{13}^{ABCD} & {μ}_{14}^{ABCD} & {μ}_{15}^{ABCD} & {μ}_{14}^{ABCD} & {μ}_{14}^{ABCD} & {μ}_{14}^{ABCD} \\ {μ}_{21}^{ABCD} & {I}_{22}^{ABCD} & {μ}_{23}^{ABCD} & {μ}_{24}^{ABCD} & {μ}_{25}^{ABCD} & {μ}_{14}^{ABCD} & {μ}_{14}^{ABCD} & {μ}_{14}^{ABCD} \\ {μ}_{31}^{ABCD} & {μ}_{32}^{ABCD} & {I}_{33}^{AB} & {μ}_{34}^{ABCD} & {μ}_{35}^{ABCD} & {μ}_{36}^{ABCD} & {μ}_{37}^{ABCD} & {μ}_{48}^{ABCD} \\ {μ}_{41}^{ABCD} & {μ}_{42}^{ABCD} & {μ}_{43}^{ABCD} & {I}_{44}^{ABCD} & {μ}_{45}^{ABCD} & {μ}_{46}^{ABCD} & {μ}_{47}^{ABCD} & {μ}_{48}^{ABCD} \\ {μ}_{51}^{ABCD} & {μ}_{52}^{ABCD} & {μ}_{53}^{ABCD} & {μ}_{54}^{ABCD} & {I}_{55}^{ABCD} & {μ}_{56}^{ABCD} & {μ}_{57}^{ABCD} & {μ}_{58}^{ABCD} \\ {μ}_{61}^{ABCD} & {μ}_{62}^{ABCD} & {μ}_{63}^{ABCD} & {μ}_{64}^{ABCD} & {μ}_{65}^{ABCD} & {I}_{66}^{ABCD} & {μ}_{67}^{ABCD} & {μ}_{68}^{ABCD} \\ {μ}_{71}^{ABCD} & {μ}_{72}^{ABCD} & {μ}_{73}^{ABCD} & {μ}_{74}^{ABCD} & {μ}_{75}^{ABCD} & {μ}_{76}^{ABCD} & {I}_{77}^{ABCD} & {μ}_{87}^{ABCD} \\ {μ}_{81}^{ABCD} & {μ}_{82}^{ABCD} & {μ}_{83}^{ABCD} & {μ}_{84}^{ABCD} & {μ}_{85}^{ABCD} & {μ}_{86}^{ABCD} & {μ}_{87}^{ABCD} & \overline{{M}_{88}^{ABCD}}\end{matrix} ]$$

Control proceeds from step 315 to step 316. In step 316, the reduced-order matrix generating portion 616 determines whether the hierarchy level is greater than zero at the joining stage. Namely, the reduced-order matrix generating portion 616 determines whether the partial structures are joined. It may be determined that the hierarchy level is greater than zero. Then, control returns to step S309 of step 315. Step 315 is repeated until the hierarchy level reaches 0 to ensure the degree of freedom for the boundary region.

When the hierarchy level reaches 0 as the determination in step 316, the process generates a system matrix whose dimension equals the sum of the degree of freedom of the boundary region and the number of eigenvalues corresponding to the reduced-order points.

The scale of the system matrix increases if the boundary region allows for too many degrees of freedom. In addition, the memory required to maintain conversion matrices used for restoration to all displacements is comparable to the product of the degree of freedom for the entire structure and the degree of freedom for the boundary region. A large amount of memory is required if there are many degrees of freedom for the entire structure and many degrees of freedom for the boundary region.

To solve this, the process in step 317 is performed. In step 317, the reduced-order matrix generating portion 616 calculates an eigenmode of the residual region. Specifically, the reduced-order matrix generating portion 616 performs operations according to equations 46 and 47. In the equations, the displacement of a contact part is expressed by eigenmode {Φ₈} resulting from the eigenvalue analysis according to equation 46. Then, equation 47 can express the displacement of the contact part by using eigenvector {Φ₈}.

[Math. 46]

[K̅₈̅₈̅^̅{̅A̅B̅C̅D̅}̅]−ω²[M̅₈̅₈̅^̅{̅A̅B̅C̅D̅}̅]{x}={0} (Math. 46)

[Math. 47]

{u₈}=[ϕ₈]{ξ₈} (Math. 47)

The displacement of reduced-order internal region i is expressed by eigenmode {Φᵢ} resulting from the eigenvalue analysis according to equation 48. Then, the connection stiffness matrix between reduced-order internal region i and the boundary region 8 becomes zero. The displacement of reduced-order internal region i is given by equation 49.

[Math. 48]

[K̅ₗ̅ₗ̅^̅{̅A̅B̅C̅D̅}̅]−ω²[M̅ₗ̅ₗ̅^̅{̅A̅B̅C̅D̅}̅]{x}={0} (Math. 48)

[Math. 49]

{uᵢ}=[ϕᵢ]{ξᵢ} (Math. 49)

Accordingly, the reduced-order matrix generating portion 616 yields conversion matrices represented by equations 50 through 54 as conversion matrices to convert partial structures into the entire structure. When the displacement of the contact part is expressed by the eigenvector, it is possible to reduce the dimensions of the conversion matrices used and retained for the restoration of all displacements and reduce computer resources and the number of calculations.

$$\begin{matrix}[ Math . 50 ] & \\ {V}_{h}^{( 2 )} = [ \begin{matrix}{ϕ}_{1}^{A} & {ψ}_{2}^{A} & 0 & 0 & 0 & 0 & 0 & 0 \\ 0 & I & 0 & 0 & 0 & 0 & 0 & 0 \\ 0 & {ψ}_{2}^{B} & {ϕ}_{3}^{B} & {ψ}_{4}^{B} & 0 & 0 & 0 & 0 \\ 0 & 0 & 0 & I & 0 & 0 & 0 & 0 \\ 0 & 0 & 0 & {ψ}_{4}^{B} & {ϕ}_{5}^{C} & {ψ}_{6}^{C} & 0 & 0 \\ 0 & 0 & 0 & 0 & 0 & I & 0 & 0 \\ 0 & 0 & 0 & 0 & 0 & {ψ}_{6}^{D} & {ϕ}_{7}^{D} & {ψ}_{8}^{D} \\ 0 & 0 & 0 & 0 & 0 & 0 & 0 & I\end{matrix} ] & ( Math . 50 )\end{matrix}$$

$$\begin{matrix}[ Math . 51 ] & \\ {V}_{h}^{( 1 )} = [ \begin{matrix}{ϕ}_{1}^{AB} & 0 & 0 & 0 & 0 & 0 & 0 & 0 \\ 0 & {ϕ}_{2}^{AB} & 0 & {ψ}_{24}^{AB} & 0 & 0 & 0 & 0 \\ 0 & 0 & {ϕ}_{3}^{AB} & 0 & 0 & 0 & 0 & 0 \\ 0 & 0 & 0 & I & 0 & 0 & 0 & 0 \\ 0 & 0 & 0 & 0 & {ϕ}_{5}^{CD} & 0 & 0 & 0 \\ 0 & 0 & 0 & {ψ}_{64}^{CD} & 0 & {ϕ}_{6}^{CD} & 0 & {ψ}_{68}^{CD} \\ 0 & 0 & 0 & 0 & 0 & 0 & {ϕ}_{7}^{CD} & 0 \\ 0 & 0 & 0 & 0 & 0 & 0 & 0 & I\end{matrix} ] & ( Math . 51 )\end{matrix}$$

$$[ Math . 52 ] \\ ( Math . 52 ) \\ {V}_{h}^{( 0 )} = \\ [ \begin{matrix}{ϕ}_{1}^{ABCD} & 0 & 0 & 0 & 0 & 0 & 0 & 0 \\ 0 & {ϕ}_{2}^{ABCD} & 0 & 0 & 0 & 0 & 0 & 0 \\ 0 & 0 & {ϕ}_{3}^{ABCD} & 0 & 0 & 0 & 0 & 0 \\ 0 & 0 & 0 & {ϕ}_{4}^{ABCD} & 0 & 0 & 0 & {ψ}_{48}^{ABCD} \\ 0 & 0 & 0 & 0 & {ϕ}_{5}^{ABCD} & 0 & 0 & 0 \\ 0 & 0 & 0 & 0 & 0 & {ϕ}_{6}^{ABCD} & 0 & 0 \\ 0 & 0 & 0 & 0 & 0 & 0 & {ϕ}_{7}^{ABCD} & 0 \\ 0 & 0 & 0 & 0 & 0 & 0 & 0 & I\end{matrix} ]$$

$$\begin{matrix}[ Math . 53 ] & \\ {V}_{h}^{( - 1 )} = [ \begin{matrix}{ϕ}_{1} & 0 & 0 & 0 & 0 & 0 & 0 & 0 \\ 0 & {ϕ}_{2} & 0 & 0 & 0 & 0 & 0 & 0 \\ 0 & 0 & {ϕ}_{3} & 0 & 0 & 0 & 0 & 0 \\ 0 & 0 & 0 & {ϕ}_{4} & 0 & 0 & 0 & 0 \\ 0 & 0 & 0 & 0 & {ϕ}_{5} & 0 & 0 & 0 \\ 0 & 0 & 0 & 0 & 0 & {ϕ}_{6} & 0 & 0 \\ 0 & 0 & 0 & 0 & 0 & 0 & {ϕ}_{7} & 0 \\ 0 & 0 & 0 & 0 & 0 & 0 & 0 & {ϕ}_{8}\end{matrix} ] & ( Math . 53 )\end{matrix}$$

$$\begin{matrix}[ Math . 54 ] & \\ {V}_{h} = {V}_{h}^{( 2 )} \cdot {V}_{h}^{( 1 )} \cdot {V}_{h}^{( 0 )} \cdot {V}_{h}^{( - 1 )} & ( Math . 54 )\end{matrix}$$

In step 318, the reduced-order matrix generating portion 616 uses the conversion matrix of equation 54 to yield reduced-order system matrices expressed in equations 55 through 58 as the final output.

The dimension of the resulting reduced-order matrix depends on the number of eigenvectors in the boundary region according to equation 46 and the number of eigenvectors in the residual region according to equation 48. It is possible to flexibly change the degree of freedom for the system matrix by changing the number of eigenvectors in the boundary region and the number of eigenvectors in the residual region according to the required calculation accuracy.

[Math. 55]

\hat{M}=[Vₕ]^{t}[M][Vₕ] (Math. 55)

[Math. 56]

\hat{K}=[Vₕ]^{t}[K][Vₕ] (Math. 56)

[Math. 57]

\hat{D}=[Vₕ]^{t}[D][Vₕ] (Math. 57)

[Math. 58]

[symbol]

=[Vₕ]^{t}{f} (Math. 58)

The conversion matrix of the boundary region may be calculated by taking into account the computer resources and retaining partially, not entirely, the boundary region. Thereby, it is possible to control the calculation amount and memory consumption for eigenvectors calculated by equation 48.

The present embodiment has described the calculation examples by using two hierarchy levels and dividing the entire structure into four partial structures. However, the resulting function effect is unchanged by an increase or decrease in the number of hierarchy levels. There is no limitation on the number of divisions applied to the entire structure.

The description below outlines the above-described processes as processes in the hardware configuration illustrated in FIG. 7. The static mode, the eigenmode, and the system matrix are stored in the HDD 621. In step 300, the CPU 6110 re-calls the static mode, the eigenmode, and the system matrix when joining partial structures and stores the static mode, the eigenmode, and the system matrix in the RAM 623. The CPU 6110 uses the static mode, the eigenmode, and the system matrix for calculations. The static mode, the eigenmode, and the system matrix are called and written repeatedly until the reduced-order matrix for the entire structure is generated. The number of repetitions equals the hierarchy level incremented by 1.

Multiple CPUs 611 may be available. In this case, each of the CPUs 6110 calculates the static mode and the eigenmode for the divided partial structures. It is possible to reduce the amount of data stored in the RAM 623 at one time. The calculation of the eigenmode and the static mode is distributed to each CPU 6110. It is possible to reduce the amount of calculation per CPU 6110 and provide high-speed processing.

The above-described processes may be performed in cooperation with other hierarchical reduced-order matrix generation devices 600 (computers) connected via the network interface 641. In this case, the hierarchical reduced-order matrix generation devices 600 share data and enable multiple CPUs 6110 included in the hierarchical reduced-order matrix generation devices 600 to perform operations. The CPUs 6110 perform step 300 to generate the system matrix and calculate the eigenmode and the static mode for divided partial structures.

The CPU 6110 temporarily stores the calculation result in its own RAM 6238. The CPU 6110 stores the calculation result in its own HDD 621 or an external storage device.

The simulation environment illustrated in the present embodiment is an example. The present invention is applicable even through the use of many other general-purpose or special-purpose simulation system environments or configurations. The invention is not limited to the environment described in the embodiment.

### REFERENCE SIGNS LIST

61 . . . Operation portion
611 . . . Data reading portion
612 . . . Boundary region reading portion
613 . . . M, K, D, F matrix generating portion
614 . . . Eigenmode count reading portion
615 . . . Static mode reading portion
616 . . . Reduced-order system matrix generating portion
62 . . . Storage portion
601 . . . Reduced-order system matrix generating program
602 . . . Physical object data
603 . . . Eigenmode
604 . . . Static mode
605 . . . Reduced-order system matrix
63 . . . Display portion
64 . . . Communication portion
65 . . . Input portion
66 . . . Connection portion

1. A hierarchical reduced-order matrix generation device that generates a hierarchical reduced-order matrix for numerical analysis of physical objects, comprising:
a storage portion that stores physical object data indicating characteristics of the physical object; and
an operation portion that generates a hierarchical reduced-order matrix for a model of the physical object data,
wherein the operation portion divides an entire structure for the model of the physical object data into a plurality of partial structures and
calculates the reduced-order matrix by using an eigenmode and a static mode in each of the divided partial structures.

2. The hierarchical reduced-order matrix generation device according to claim 1,
wherein the operation portion
classifies each of divided partial structures into an internal region eliminating the degree of freedom, a boundary region retaining the degree of freedom, and an adjacent region between partial structures,
calculates an eigenmode for the internal region,
calculates a static mode for the adjacent region and the boundary region, and
calculates the reduced-order matrix by using the eigenmode for the internal region and the static mode for the adjacent region and the boundary region.

3. The hierarchical reduced-order matrix generation device according to claim 2,
wherein the operation portion
stepwise divides the entire structure into a plurality of partial structures and
calculates the reduced-order matrix by reducing orders and joining each of the partial structures in order from a lower layer to a higher layer.

4. The hierarchical reduced-order matrix generation device according to claim 1,
wherein the operation portion stepwise performs the division into the partial structures.

5. The hierarchical reduced-order matrix generation device according to claim 1
wherein the operation portion performs the division into the partial structures all at once.

6. A computer-readable medium storing a program allowing a computer to function as a hierarchical reduced-order matrix generation device that generates a hierarchical reduced-order matrix for numerical analysis of physical objects,
wherein the computer includes a storage portion that stores physical object data indicating characteristics of the physical object; and
wherein the computer is allowed to perform the steps of dividing an entire structure for the model of the physical object data into a plurality of partial structures and calculating the reduced-order matrix by using an eigenmode and a static mode in each of the divided partial structures.

7. The computer-readable medium storing the program according to claim 6, allowing the computer to perform the steps of:
classifying each of divided partial structures into an internal region eliminating the degree of freedom, a boundary region retaining the degree of freedom, and an adjacent region between partial structures;
calculating an eigenmode for the internal region;
calculating a static mode for the adjacent region and the boundary region; and
calculating the reduced-order matrix by using the eigenmode for the internal region and the static mode for the adjacent region and the boundary region.

8. The computer-readable medium storing the program according to claim 7, allowing the computer to perform the steps of:
stepwise dividing the entire structure into a plurality of partial structures; and
calculating the reduced-order matrix by reducing orders and joining each of the partial structures in order from a lower layer to a higher layer.

9. The computer readable medium storing the program according to claim 6, allowing the computer to perform the step of:
stepwise performing the division into the partial structures.

10. The computer-readable medium storing the program according to claim 6, allowing the computer to perform the step of:
performing the division into the partial structures all at once.
